(19) United States
(12) Patent Application Publication
(10) Pub. No.: US 2021/0020537 A1
(43) Pub. Date: Jan. 21, 2021

(54) INTEGRATED HEAT SPREADER (IHS) WITH SOLDER THERMAL INTERFACE MATERIAL (STIM) BLEED-OUT RESTRICTING FEATURE

(71) Applicant: Intel Corporation, Santa Clara, CA (US)

(72) Inventors: Sergio Antonio Chan Arguedas, Chandler, AZ (US); Manish Dubey, Chandler, AZ (US); Peng Li, Chandler, AZ (US); Aravindha R. Antoniswamy, Phoenix, AZ (US); Anup Pancholi, Hillsboro, OR (US)

(73) Assignee: Intel Corporation, Santa Clara, CA (US)

(21) Appl. No.: 16/516,692

(22) Filed: Jul. 19, 2019

(51) Int. Cl. H01L 23/367; H01L 23/00

(52) U.S. Cl. CPC H01L 23/3675; H01L 24/73; H01L 24/32; H01L 23/3736; H01L 24/83; H01L 2224/73204; H01L 24/29

(57) ABSTRACT

Embodiments may relate to a microelectronic package that includes a die coupled with a package substrate. A solder thermal interface material (STIM) may be coupled with the die such that the die is between the STIM and the package substrate. An integrated heat spreader (IHS) may be coupled with the STIM such that the STIM is between the IHS and the die, and the IHS may include a feature that is to control bleed-out of the STIM during STIM reflow based on surface tension of the STIM. Other embodiments may be described or claimed.

### BACKGROUND

Microelectronic packages that utilize solder thermal interface material (STIM) may have a relatively large require of clear space between the die and the integrated heat spreader (IHS) or other components of the microelectronic package. This clear space may be to prevent liquid STIM that is created during the STIM reflow process from touching adjacent components and creating electrical shorts. This limitation may result in a relatively large microelectronic package size that includes unused space.

### BRIEF DESCRIPTION OF THE DRAWINGS

FIG. 1 depicts an example cross-sectional view of a microelectronic package with a bleed-out restricting feature, in accordance with various embodiments.

FIG. 2 depicts an alternative example cross-sectional view of a microelectronic package with a bleed-out restricting feature, in accordance with various embodiments.

FIG. 3 depicts an alternative example cross-sectional view of a microelectronic package with a bleed-out restricting feature, in accordance with various embodiments.

FIG. 4 depicts an alternative example cross-sectional view of a microelectronic package with a bleed-out restricting feature, in accordance with various embodiments.

FIG. 5 depicts an alternative example cross-sectional view of a microelectronic package with a bleed-out restricting feature, in accordance with various embodiments.

FIG. 6 depicts an example top-down view of a microelectronic package with a bleed-out restricting feature, in accordance with various embodiments.

FIG. 7 depicts an example technique for the manufacture of a microelectronic package with a bleed-out restricting feature, in accordance with various embodiments.

FIG. 8 is a top view of a wafer and dies that may be used in a microelectronic package with a bleed-out restricting feature, in accordance with various embodiments.

FIG. 9 is a side, cross-sectional view of an integrated circuit (IC) device assembly that may include a microelectronic package with a bleed-out restricting feature, in accordance with various embodiments.

FIG. 10 is a block diagram of an example electrical device that may include a microelectronic package with a bleed-out restricting feature, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature [[formed/deposited/disposed/etc.]] on a second feature,” may mean that the first feature is formed/deposited/disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Embodiments herein may address the above-described package real-estate limitations. Specifically, embodiments herein may include one or more features on or around the IHS. The features may include a well-defined or “sharp” edge near the periphery of the die. The well-defined edges of the features may limit the degree to which the STIM may bleed-out during reflow based on surface tension of the STIM. Specifically, the surface tension of the liquid STIM may interact with the well-defined edges and act as a containment mechanism for the liquid STIM. At a high level, the contact angle of a droplet in a flat surface may be given towards a surface angle of approximately 180°. When the liquid reaches an edge (e.g., a physical structure with an approximately 90° angle), the surface tension of the liquid may change as the equilibrium contact angle increases. This change may cause the liquid to form a higher concave meniscus before it breaks equilibrium and continues spreading. Examples of such features with an edge may include pedestals, cavities, trenches, etc., as will be described in greater detail below. As a result of the containment of the liquid STIM, embodiments may reduce, mitigate, or negate the requirement for an extended clear zone in the microelectronic package on at least one side of the die, which may help to optimize package size or layout. Specifically, the unused space in the microelectronic package which is related to the need for a clear zone may be reduced or negated.

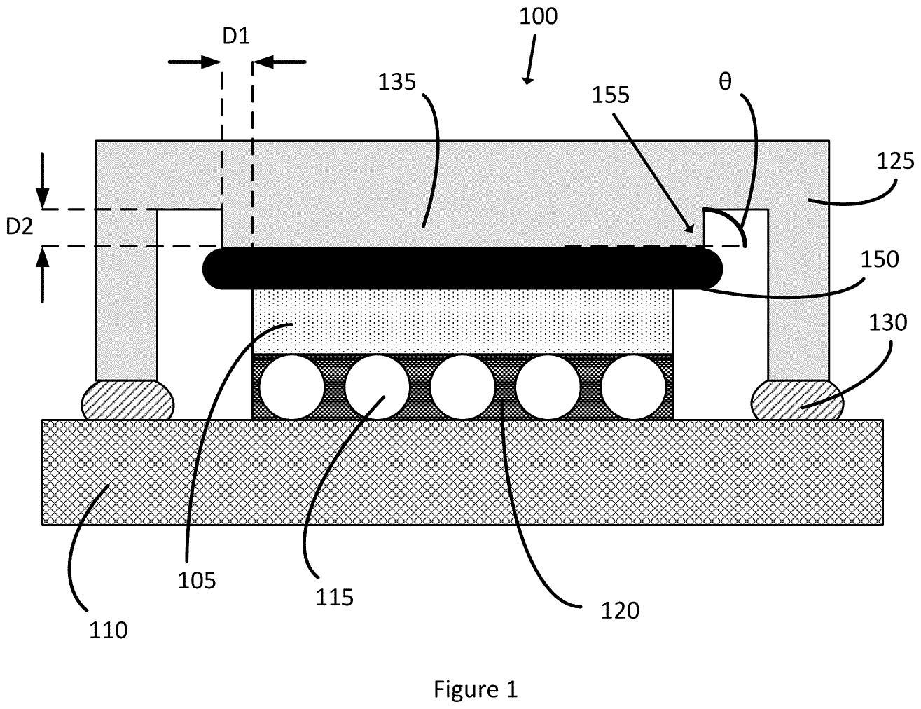

FIG. 1 depicts an example microelectronic package 100 with a bleed-out restricting feature, in accordance with various embodiments. Generally, the package 100 may include a die 105 coupled with a package substrate 110. The die 105 may be or include, for example, a processor such as a central processing unit (CPU), graphics processing unit (GPU), a core of a distributed processor, or some other type of processor. Alternatively, the die 105 may be include a memory such as a double data rate (DDR) memory, a nonvolatile memory (NVM), a volatile memory, a read-only memory (ROM), or some other type of memory or die. In some embodiments the die 105 may be or include a radio frequency (RF) chip or RF circuitry that is configured to generate, process, transmit, or receive a wireless signal such as a third generation (3G), a fourth generation (4G), a fifth generation (5G), a Wi-Fi, or some other type of wireless signal. In some embodiments the die 105 may include one or more passive components such as capacitors, resistors, etc. The various active or passive components may be positioned within, partially within, or on the surface of the die 105.

The package substrate 110 may be, for example, considered to be a cored or coreless substrate. The package substrate 110 may include one or more layers of a dielectric material which may be organic or inorganic. The package substrate 110 may further include one or more conductive elements such as vias, pads, traces, microstrips, striplines, etc. The conductive elements may be internal to, or on the surface of, the package substrate. Generally, the conductive elements may allow for the routing of signals through the package substrate 110, or between elements that are coupled to the package substrate 110. In some embodiments the package substrate 110 may be, for example, a printed circuit board (PCB), an interposer, a motherboard, or some other type of substrate. It will be understood that although the package substrate 110 is discussed herein as an element of the microelectronic package 100, in other embodiments the package substrate 110 may be considered to be an element separate from the microelectronic package 100 to which the microelectronic package 100 is coupled.

Generally, the die 105 may be coupled with the package substrate 110 by one or more interconnects 115. The interconnects 115 may be, for example, solder bumps that are formed of a material such as tin, silver, copper, etc. If solder bumps are used for the interconnects 115, then the solder bumps may be elements of a ball grid array (BGA) as shown in FIG. 1. In other embodiments, the interconnects 115 may be pins of a pin grid array (PGA), elements of a land grid array (LGA), or some other type of interconnect. Generally, the interconnects 115 may physically or communicatively couple the die 105 with the package substrate 110. For example, one or more of the interconnects 115 may physically couple with, and allow electrical signals to pass between, pads of the die 105 and pads of the package substrate 110 (not shown for the sake of elimination of clutter of FIG. 1). In other embodiments, the interconnects 115 may physically couple the die 105 and the package substrate 110, but the interconnects 115 may not communicatively couple the die 105 and the package substrate 110.

The microelectronic package may further include an underfill material 120. The underfill material 120 may at least partially surround the interconnects 115, and may at least partially fill the space between the die 105 and the package substrate 110. Generally, the underfill material 120 may lend further structural stability to the microelectronic package 100 and strengthen the connection between the die 105 and the package substrate 110. The underfill material 120 may be formed of a polymer material such as epoxy or some other material.

The microelectronic package 100 may further include a STIM layer 150. The STIM layer 150 may be formed of a solder material such as indium or some other material. Generally, the STIM layer 150 may be considered to be a thermally conductive material. In embodiments, the STIM 150 may be placed on the package, prior to STIM reflow, as a preformed element that is placed on the die 105. In other embodiments the STIM 150 may be placed on the package, prior to STIM reflow, as a sprayed or printed element that is

The STIM layer 150 may couple with an IHS 125. The IHS 125 may be formed of a thermally conductive material such as copper or some other material. The IHS 125 may couple with a thermal solution such as a vapor chamber, a water-cooled cooling apparatus, fins, or some other type of thermal solution. The thermal solution is not depicted in FIG. 1 for the sake of reduction of clutter of the Figure. In operation, the STIM layer 150 may serve to draw thermal energy from the die 105. The thermal energy may be generated through operation of the die 105 and, if the die 105 is a high-performance die, then the die 105 may generate a significant amount of thermal energy. The thermal energy may travel from the STIM layer 150 to the IHS 125 where the thermal energy may then be dispersed through the IHS 125. The IHS 125 may transfer the thermal energy to the thermal solution where the thermal energy may be dispersed away from the microelectronic package 100.

In embodiments, the IHS 125 may be coupled with the package substrate 110. Specifically, the IHS may be coupled with the package substrate 110 by a sealant 130 as shown in FIG. 1. The sealant 130 may be conductive or non-conductive in nature. That is, in some embodiments the sealant 130 may couple with conductive elements of the IHS 125 and the package substrate 110 (e.g., pads) and route electrical signals between the two elements in addition to physically coupling the package substrate 110 and the IHS 125. In other embodiments, the sealant 130 may not route electrical signals.

As can be seen in FIG. 1, in some embodiments the IHS 125 may include a bleed-out restricting feature 135 as described above. As depicted in FIG. 1, the feature 135 may be referred to as a “pedestal.” Specifically, the feature 135 may extend away from the face of the IHS 125 by a distance D2. In embodiments, the distance D2 may be between approximately 0.1 millimeters (mm) and approximately 0.6 mm. Generally, it will be understood that in other embodiments D2 may be greater or smaller based on one or more factors such as the material of the IHS, the material of the STIM, the use case to which the microelectronic package 100 will be put, design considerations of the microelectronic package 100, the type of die 105, etc.

Additionally, it can be seen that the feature 135 may extend beyond the periphery of the die 105 by a distance D1. Specifically, the footprint of the feature 135 may be larger than the footprint of the die 105. As used herein, the “footprint” of an element may refer to a lateral size of the element as oriented in FIG. 1. For example, the “footprint” of the die 105 may refer to a size of the die 105 as measured in a plane parallel to the face of the package substrate 110 to which the die 105 is coupled. In embodiments, D1 may be between approximately 500 nanometers (nm) and approximately 1 mm. However, similarly to D2, it will be understood that in other embodiments the distance D1 may be larger or smaller than stated above based on one or more of the factors discussed above with respect to D2.

As noted above, the feature 135 may include a well-defined or “sharp” edge 155 which may interact with the STIM 150 and serve to constrain the STIM 150 based on surface tension when the STIM 150 is in a liquid or semi-liquid state during STIM reflow. As can be seen, the edge 155 may have an angle θ of approximately 90°. However, it will be understood that the angle θ of the edge may be greater or lesser than depicted based on factors such as the type of STIM used, the length of the reflow process, etc. In some embodiments, the angle θ may be between approximately 70° and approximately 110°. In other embodiments the angle θ may be between approximately 85° and approximately 95°. In other embodiments, as stated above, the angle θ may be approximately 90°. As can be seen, the STIM 150 may extend at least partially beyond the edge 155, however it may generally be noted that the edge 155 may serve to constrain the extension of the STIM 150 in a predicted manner such that the need for a clear zone around the die 105 may be reduced or eliminated.

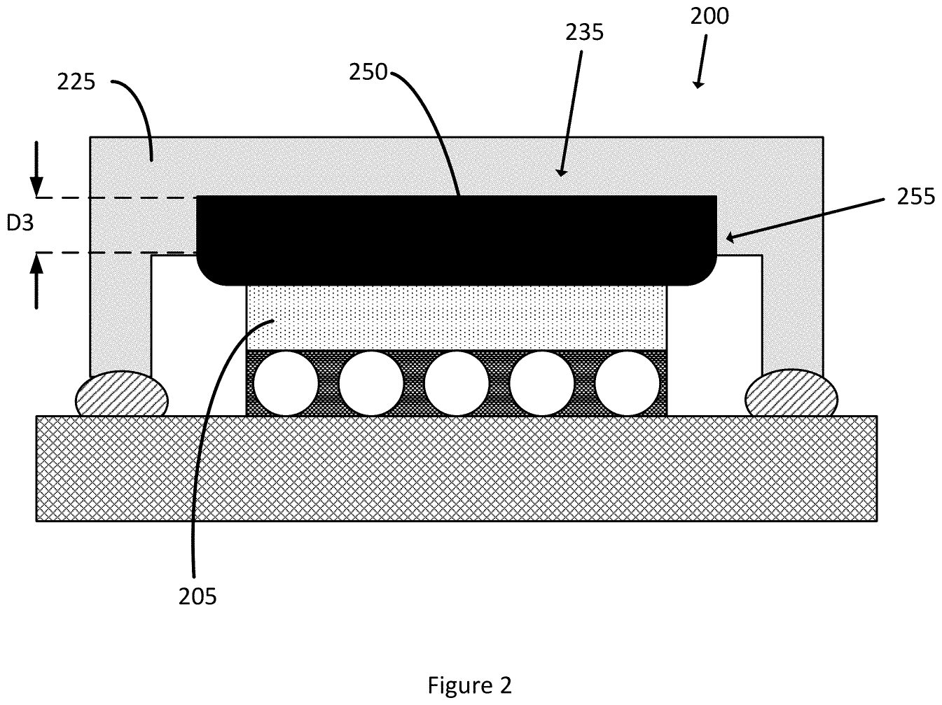

FIG. 2 depicts an alternative example cross-sectional view of a microelectronic package 200 with a bleed-out restricting feature, in accordance with various embodiments. Generally, it will be understood that each and every element of the following FIGS. 2-5 may not be explicitly enumerated or described for the sake of brevity and lack of redundancy, however it will be understood that various elements in the Figures that appear identical to elements of FIG. 1 (e.g., the interconnects, underfill, sealant, etc.) may be similar to, and share one or more characteristics with, those elements of FIG. 1.

The microelectronic package 200 may include a die 205, a STIM 250, and an IHS 225, which may be respectively similar to, and share one or more characteristics with, die 105, STIM 150, and IHS 125. Further, as can be seen in FIG. 2, the IHS 225 may include a feature 235 with a well-defined edge 255. In contrast to feature 135 which generally extended from the face of the IHS 125, the feature 235 may be a cavity that is generally recessed into the IHS 225. In embodiments, the feature 235 may be recessed by a distance D3 which may be between approximately 0.05 mm and approximately 0.6 mm. However, similarly to distances D1 or D2, D3 may be dependent on a variety of factors such as those described above with respect to distance D2.

As can be seen, edge 255 may, similarly to edge 155, be a “sharp” or well-defined edge. The STIM 250 may generally fill the cavity of the feature 235, and the edge 255 may prevent the STIM 250 from extending beyond a pre-defined distance due to surface tension of the STIM 250 during reflow as discussed above.

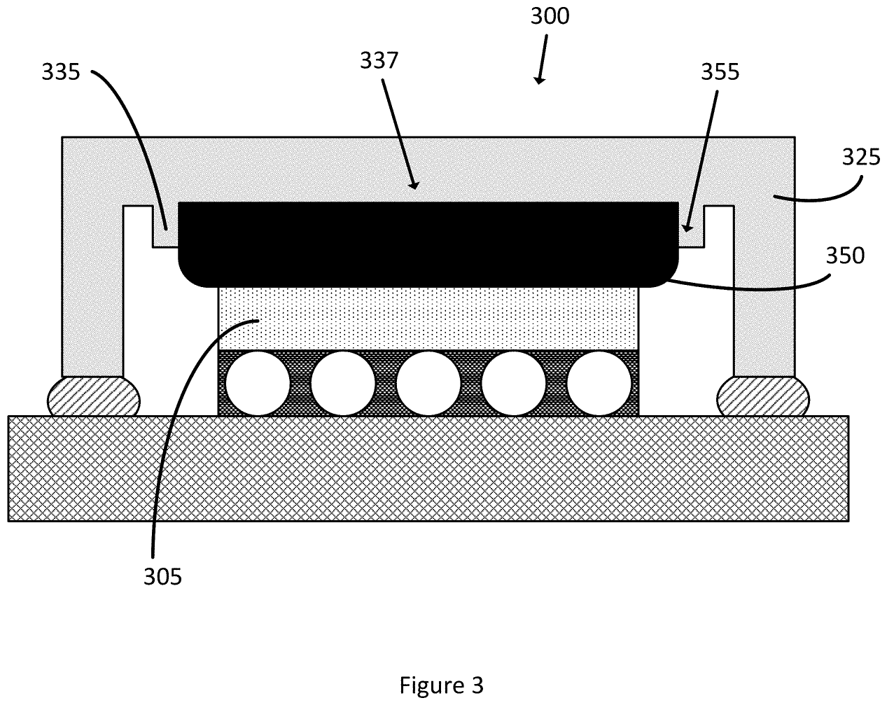

FIG. 3 depicts an alternative example cross-sectional view of a microelectronic package 300 with a bleed-out restricting feature, in accordance with various embodiments. The microelectronic package 300 may include a die 305, a STIM 350, and an IHS 325, which may be respectively similar to, and share one or more characteristics with, die 105, STIM 150, and IHS 125. Further, as can be seen in FIG. 3, the IHS 325 may include a feature 335 with a well-defined edge 355. Generally, the feature 335 may be viewed as a combination of the pedestal of FIG. 1 and the cavity of FIG. 2. Such a feature 335 may be referred to as a “trench” wherein the feature 335 protrudes from the face of the IHS 325 in a pedestal-like configuration, but includes a cavity 337 that is recessed into the pedestal. The distance to which the pedestal portion of the feature protrudes 335 may be similar to distance D2 discussed above. The extent to which the cavity 337 is recessed into the feature 335 may be similar to distance D3 discussed above. However, as noted above, the distances of protrusion or recess may be different in different embodiments based on one or more of the factors described above with respect to distance D2.

As can be seen, edge 355 may, similarly to edge 155, be a “sharp” or well-defined edge. The STIM 350 may generally fill the cavity 337 of the feature 335, and the edge 355 may prevent the STIM 350 from extending beyond a pre-defined distance due to surface tension of the STIM 350 during reflow as discussed above.

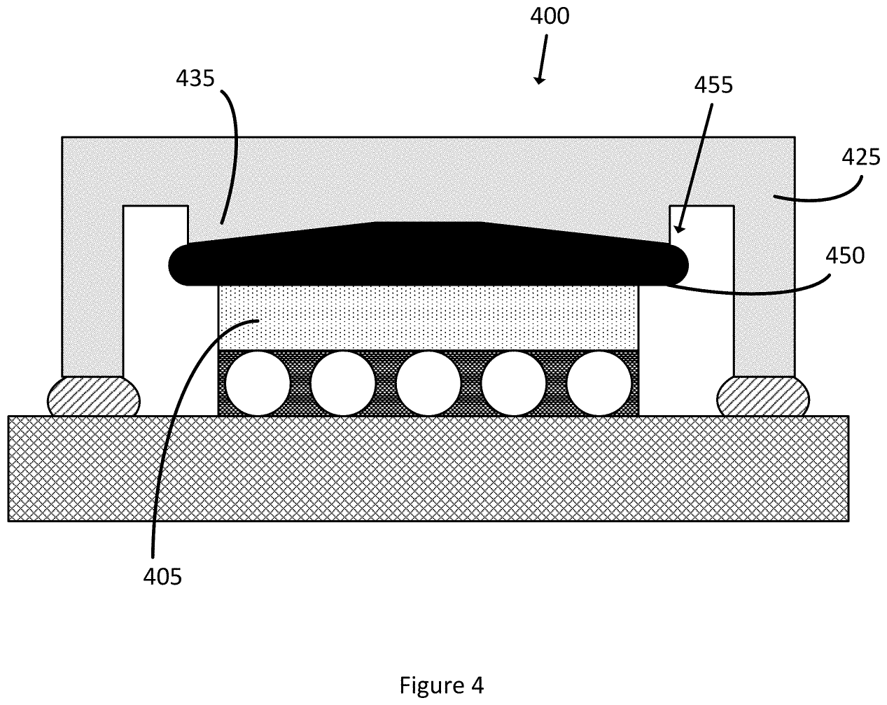

FIG. 4 depicts an alternative example cross-sectional view of a microelectronic package 400 with a bleed-out restricting feature, in accordance with various embodiments. The microelectronic package 400 may include a die 405, a STIM 450, and an IHS 425, which may be respectively similar to, and share one or more characteristics with, die 105, STIM 150, and IHS 125. Further, as can be seen in FIG. 4, the IHS 425 may include a feature 435 with a well-defined edge 455. As can be seen, edge 455 may, similarly to edge 155, be a “sharp” or well-defined edge. The STIM 450 may generally be coupled with the feature 435, and the edge 455 may prevent the STIM 450 from extending beyond a pre-defined distance due to surface tension of the STIM 450 during reflow as discussed above.

Generally, the feature 435 may be considered to be a pedestal similar to the feature 135 of FIG. 1. However, as can be seen in FIG. 4, the pedestal may have a non-linear profile. Specifically, the feature 435 may be generally concave such that a central portion of the feature 435 is further from the die 405 than an outer portion of the feature 435. Such a design may be desirable when, for example, it is known that a certain portion of the die 405 may generate more heat than another portion of the die 405, and so it may be desirable to have a thicker layer of STIM 450 in that area. Additionally or alternatively, the non-uniform profile may be desirable to compensate for or otherwise affect physical stress of the microelectronic package 400.

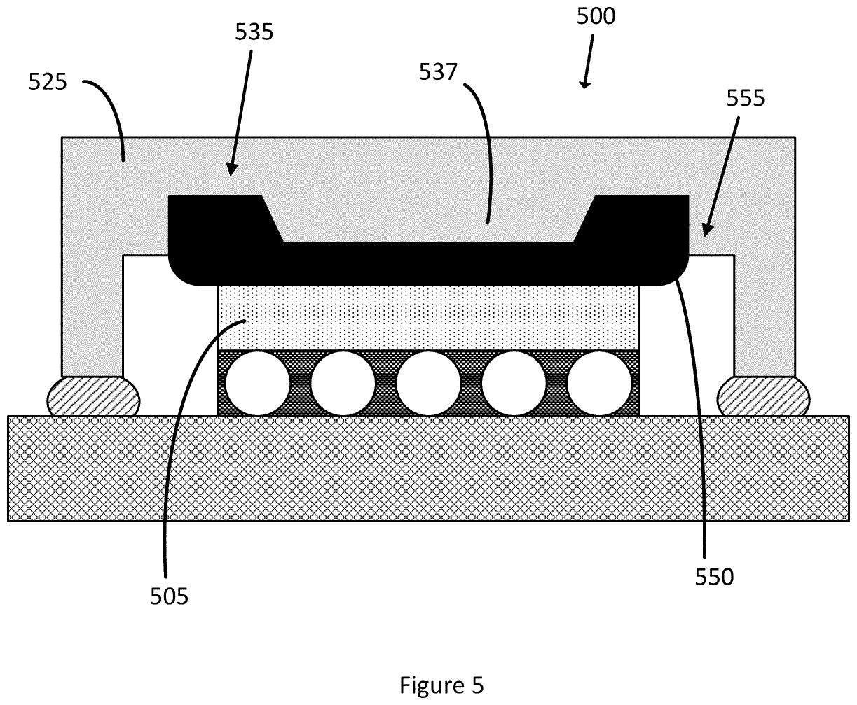

FIG. 5 depicts an alternative example cross-sectional view of a microelectronic package 500 with a bleed-out restricting feature, in accordance with various embodiments. The microelectronic package 500 may include a die 505, a STIM 550, and an IHS 525, which may be respectively similar to, and share one or more characteristics with, die 105, STIM 150, and IHS 125. Further, as can be seen in FIG. 5, the IHS 525 may include a feature 535 with a well-defined edge 555. The edge 555 may, similarly to edge 155, be a “sharp” or well-defined edge. The STIM 550 may generally be coupled with the feature 535, and the edge 555 may prevent the STIM 550 from extending beyond a pre-defined distance due to surface tension of the STIM 550 during reflow as discussed above.

As can be seen in FIG. 5, the feature 535 may be generally similar to the cavity-type feature 235 of FIG. 2. However, the feature 535 may include a protrusion 537 that at least partially extends from the IHS 525 into the cavity, making the STIM 550 thinner at a central portion of the STIM 550, and thicker at a portion around the periphery of the STIM 550. Similarly to feature 435, this type of non-linear or non-uniform profile may be desirable if there are certain thermal “hot spots,” stresses of the microelectronic package 500, etc. that may be affected by altering the thickness of the IHS 525 or the STIM 550.

It will be understood that the specific designs depicted in the Figures above are intended as examples of various embodiments, and other embodiments may have one or more variations from what is depicted. For example, other embodiments may have more or fewer elements, or alternative elements. Some embodiments may have additional active or passive components in or on various layers or elements of the microelectronic packages. Some embodiments may have more or fewer interconnects than depicted. Some embodiments may replace the sealant with a series of interconnects with or without additional underfill. The relative sizes or dimensions of certain elements such as the STIM or the IHS may be larger or smaller than depicted. Generally, it will be recognized that the dimensions depicted are shown for the sake of illustration of concepts and, unless otherwise stated, the relative dimensions of elements should not be taken as indicative of the relative sizes of the elements in real-world embodiments. Additionally, although elements of FIGS. 2-5 may be described with reference to elements of FIG. 1, it will be recognized that similar elements between FIGS. 2-5 (e.g., the various IHSs, dies, STIMs, etc.) may likewise share one or more characteristics with one another

Additionally, it will be recognized that FIGS. 4 and 5 are intended as examples of features 435/535 with a non-linear or non-uniform profile, and other embodiments may have different profiles. In some embodiments, the profile of a feature may be linear, but may not be parallel to the face of the die 405/505 or the face of the package substrate to which the die is coupled. For example, the feature 435/535 could have a linear profile that was slanted at some angle. Additionally, some embodiments may include combinations of depicted elements. For example, the trench-like feature of FIG. 3 may include a non-linear or non-uniform face as depicted in FIG. 4 or 5. Other variations may be present in other embodiments.

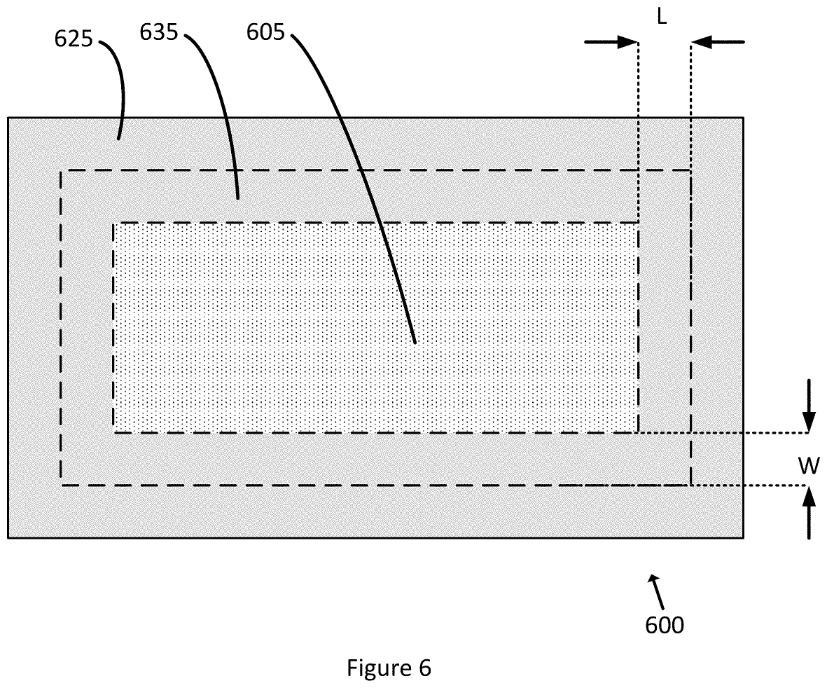

FIG. 6 depicts an example top-down view of a microelectronic package 600 with a bleed-out restricting feature, in accordance with various embodiments. Generally, it will be understood that FIG. 6 is intended as a highly simplified example to show relative lateral sizes, and each and every element of the package may not be present.

Generally, the microelectronic package 600 may include a die 605, a feature 635, and an IHS 625, which may be respectively similar to, and share one or more characteristics with, die 105, feature 135, and IHS 125 (or some other die/feature/IHS discussed herein).

As described above, the feature 135 may have a footprint that is greater than the footprint of the die 105. Specifically, the feature 135 may extend beyond the footprint of the die 105 by a distance D1. As can be seen in FIG. 6, the feature 635 may extend beyond the periphery of the die in accordance with both a length L and a width W of the die. In embodiments, L and W may be equal to one another, whereas in other embodiments L may be different than W. In some embodiments L, or W, or both may be equal to D1. It will be understood that the distances L and W may be dependent on one or more of the factors described above with respect to distance D2. Additionally, it will be understood that although the die 605, feature 635, and IHS 625 are depicted as being generally rectangular, in other embodiments one or more of the die 605, feature 635, and IHS 625 may have a different cross-section such as a square, circle, triangle, hexagon, non-uniform shape, etc. Other variations may be present in other embodiments.

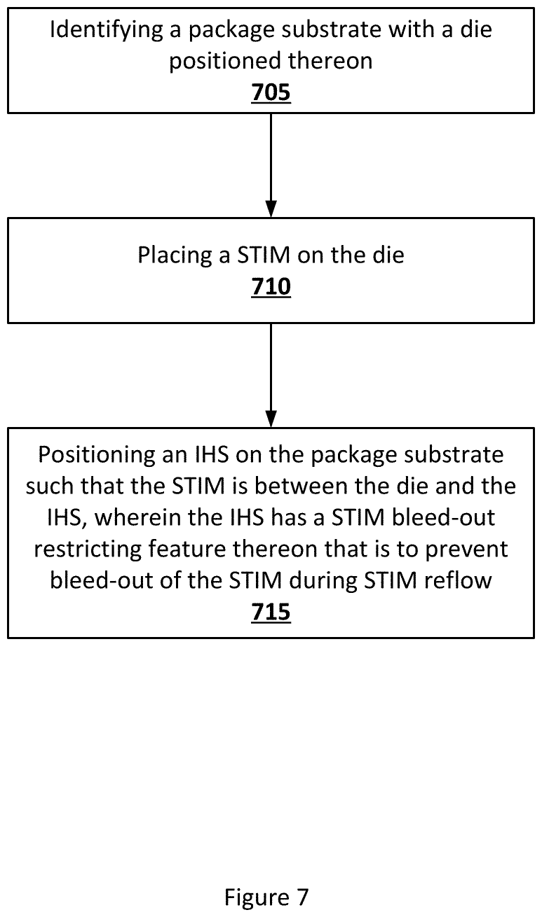

FIG. 7 depicts an example technique for the manufacture of a microelectronic package with a bleed-out restricting feature, in accordance with various embodiments. It will be understood that FIG. 7 may be described with respect to elements of the embodiment of FIG. 1, however the technique may be applicable, in whole or in part, with or without modification, to other embodiments herein. Additionally, it will be understood that FIG. 7 is a highly simplified example technique, and other embodiments may have more or fewer elements, or elements arranged in a different order than depicted in FIG. 7. Other variations may be present in other embodiments.

The technique may include identifying, at 705, a package substrate with a die positioned thereon. The package substrate may be similar to, for example, package substrate 110. The die may be similar to, for example, die 105.

The technique may further include placing, at 710, a STIM on the die. The STIM may be similar to, for example, STIM 150. In some embodiments, placing the STIM on the die may include placing a STIM preform on the die. In other embodiments, placing the STIM on the die may include depositing by spraying, printing, or some other deposition technique, the STIM on an IHS such as IHS 125 so that when the IHS is coupled with the package substrate the STIM is placed on the die. Other forms of placement of the STIM on the die may be present in other embodiments.

The technique may further include positioning, at 715, an IHS on the package substrate such that the STIM is between the die and the IHS. The IHS may be similar to, for example, IHS 125. The IHS may have a STIM bleed-out restricting feature such as feature 135. The STIM bleed-out restricting feature may serve to prevent bleed-out of the STIM during STIM reflow as described above.

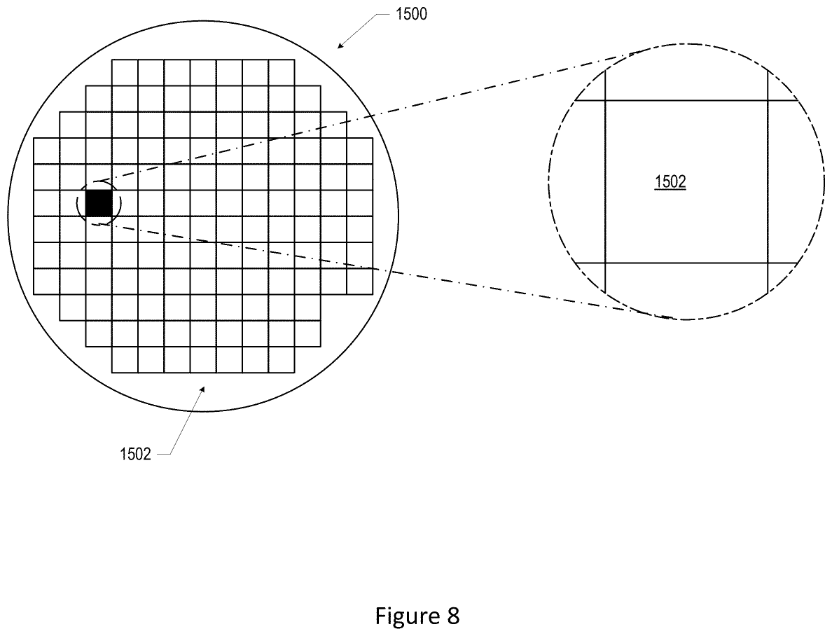

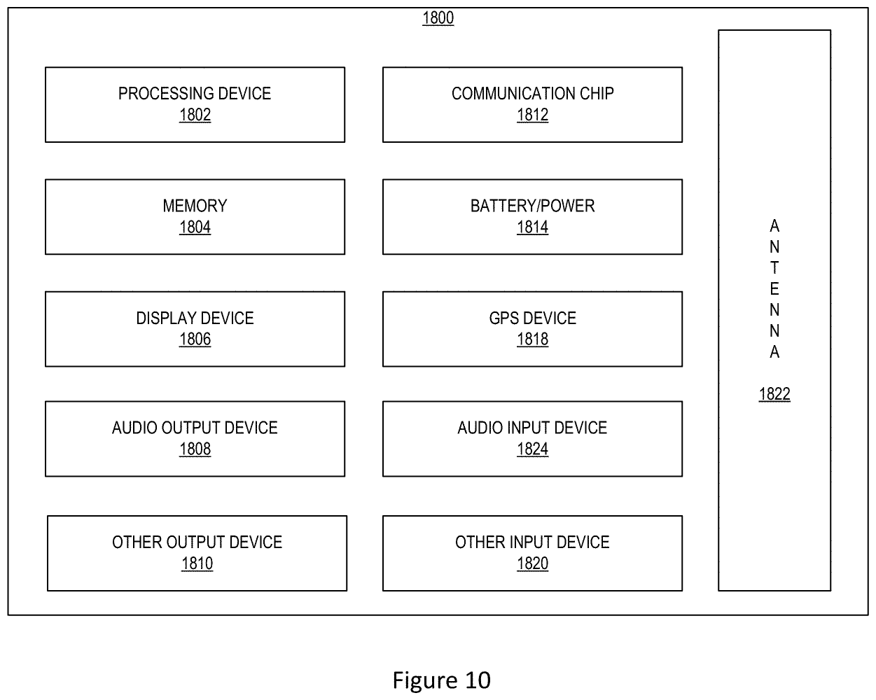

FIG. 8 is a top view of a wafer 1500 and dies 1502 that may be used in a microelectronic package with a bleed-out restricting feature. For example, dies 1502 may be similar to dies 105/205/305/etc. as described herein. The wafer 1500 may be composed of semiconductor material and may include one or more dies 1502 having IC structures formed on a surface of the wafer 1500. Each of the dies 1502 may be a repeating unit of a semiconductor product that includes a suitable IC. After the fabrication of the semiconductor product is complete, the wafer 1500 may undergo a singulation process in which the dies 1502 are separated from one another to provide discrete “chips” of the semiconductor product. The die 1502 may include one or more transistors or supporting circuitry to route electrical signals to the transistors, or some other IC component. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

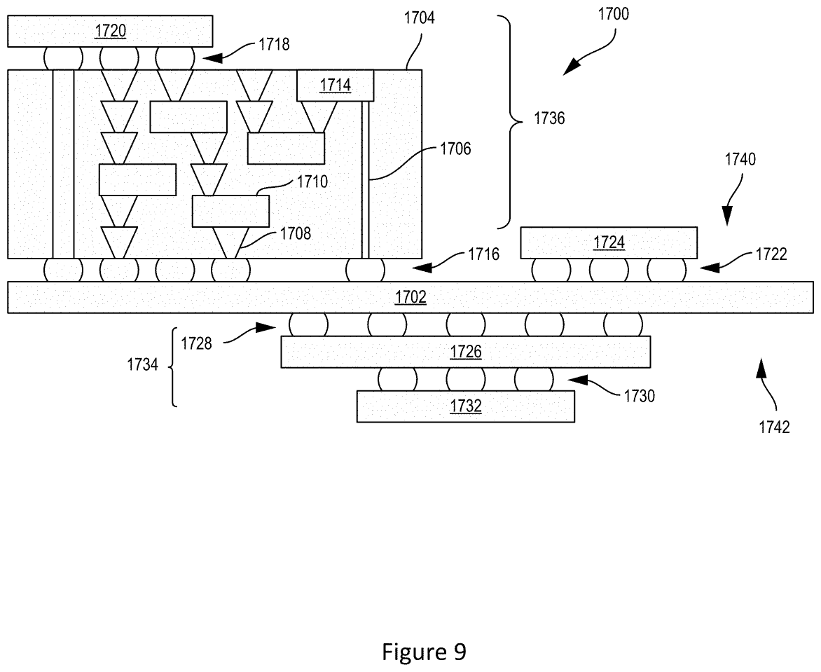

FIG. 9 is a side, cross-sectional view of an IC device assembly 1700 that may include one or more IC packages or other electronic components (e.g., a die) including one or more microelectronic packages with a bleed-out restricting feature, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 9, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more microelectronic packages with a bleed-out restricting feature.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more microelectronic packages with a bleed-out restricting feature, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), CPUs, GPUs, cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., ROM), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### Examples of Various Embodiments

Example 1 includes a microelectronic package comprising: a package substrate; a die coupled with a package substrate; a STIM coupled with the die such that the die is between the STIM and the package substrate; and an IHS coupled with the STIM such that the STIM is between the IHS and the die, wherein the IHS includes a feature that is to control bleed-out of the STIM during STIM reflow based on surface tension of the STIM.

Example 2 includes the microelectronic package of example 1, wherein the feature includes an edge with an angle of greater than 70 degrees, and wherein the STIM is to interact with the edge during STIM reflow to control bleed-out of the STIM based on surface tension of the STIM.

Example 3 includes the microelectronic package of example 1, wherein the feature is a protrusion from the IHS in a direction towards the STIM.

Example 4 includes the microelectronic package of example 1, wherein the feature is a cavity in the IHS.

Example 5 includes the microelectronic package of any of examples 1-4, wherein the feature has a footprint greater than a footprint of the die.

Example 6 includes the microelectronic package of example 5, wherein the footprint of the feature is measured in a direction perpendicular to a face of the package substrate to which the die is coupled.

Example 7 includes a microelectronic package comprising: a die; a STIM coupled with the die; and an IHS coupled with the STIM such that the STIM is between the IHS and the die, wherein: the IHS includes a pedestal that protrudes from a face of the IHS; the STIM is coupled with the pedestal; and the pedestal has a footprint that is larger than a footprint of the die.

Example 8 includes the microelectronic package of example 7, wherein the footprint of the pedestal extends beyond the footprint of the die by greater than 500 micrometers.

Example 9 includes the microelectronic package of example 8, wherein the footprint of the pedestal extends beyond the footprint of the die by between 500 micrometers and 1 millimeter.

Example 10 includes the microelectronic package of any of examples 7-9, wherein the pedestal includes a cavity, and the cavity of the pedestal is coupled with the STIM.

Example 11 includes the microelectronic package of any of examples 7-9, wherein the STIM includes indium.

Example 12 includes the microelectronic package of any of examples 7-9, wherein the pedestal includes a face that is coupled with the STIM, and wherein the face is not parallel to a face of the die to which the STIM is coupled.

Example 13 includes the microelectronic package of any of examples 7-9, wherein the pedestal is to control bleed-out of the STIM during STIM reflow.

Example 14 includes a microelectronic package comprising: a die; a STIM coupled with the die; and an IHS wherein the IHS includes a cavity in the IHS, and the STIM is coupled with the IHS inside the cavity.

Example 15 includes the microelectronic package of example 14, wherein the cavity has a footprint that is greater than a footprint of the die.

Example 16 includes the microelectronic package of example 15, wherein the footprint of the cavity is greater than the footprint of the die by at least 1 millimeter.

Example 17 includes the microelectronic package of any of examples 14-16, wherein the cavity extends beyond the die by at least 500 nanometers around the periphery of the die.

Example 18 includes the microelectronic package of any of examples 14-16, wherein the cavity is to control bleed-out of the STIM during a STIM reflow process.

Example 19 includes the microelectronic package of any of examples 14-16, wherein a face of the cavity to which the STIM is coupled has a non-linear profile.

Example 20 includes the microelectronic package of any of examples 14-16, wherein the STIM includes indium.

Example 21 includes a method of forming a microelectronic package, wherein the method comprises: identifying a package substrate with a die positioned thereon; placing a STIM on the die; and positioning an IHS on the package substrate such that the STIM is between the die and the IHS, wherein the IHS has a STIM bleed-out restricting feature thereon that is to prevent bleed-out of the STIM during STIM reflow.

Example 22 includes the method of example 21, wherein the feature is a pedestal.

Example 23 includes the method of example 21, wherein the feature is a cavity.

Example 24 includes the method of example 21, wherein the feature is a trench.

Example 25 includes the method of example 21, wherein the feature has a non-uniform profile.

Example 26 includes the method of any of examples 21-25, further comprising performing STIM reflow subsequent to the positioning of the IHS.

Example 27 includes the method of any of examples 21-25, wherein the placing the STIM includes placing a STIM preform on the die.

Example 28 includes the method of any of examples 21-25, wherein the placing the STIM includes depositing the STIM on the feature of the IHS such that when the IHS is positioned on the package substrate the STIM is placed on the die.

Example 29 includes the method of any of examples 21-25, wherein the bleed-out restricting feature is to prevent bleed-out of the STIM based on surface tension of the liquid STIM.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A microelectronic package comprising:
a package substrate;
a die coupled with a package substrate;
a solder thermal interface material (STIM) coupled with the die such that the die is between the STIM and the package substrate; and
an integrated heat spreader (IHS) coupled with the STIM such that the STIM is between the IHS and the die, wherein the IHS includes a feature that is to control bleed-out of the STIM during STIM reflow based on surface tension of the STIM.

2. The microelectronic package of claim 1, wherein the feature includes an edge with an angle of greater than 70 degrees, and wherein the STIM is to interact with the edge during STIM reflow to control bleed-out of the STIM based on surface tension of the STIM.

3. The microelectronic package of claim 1, wherein the feature is a protrusion from the IHS in a direction towards the STIM.

4. The microelectronic package of claim 1, wherein the feature is a cavity in the IHS.

5. The microelectronic package of claim 1, wherein the feature has a footprint greater than a footprint of the die.

6. The microelectronic package of claim 5, wherein the footprint of the feature is measured in a direction perpendicular to a face of the package substrate to which the die is coupled.

7. A microelectronic package comprising:
a die;
a solder thermal interface material (STIM) coupled with the die; and
an integrated heat spreader (IHS) coupled with the STIM such that the STIM is between the IHS and the die, wherein:
the IHS includes a pedestal that protrudes from a face of the IHS;
the STIM is coupled with the pedestal; and
the pedestal has a footprint that is larger than a footprint of the die.

8. The microelectronic package of claim 7, wherein the footprint of the pedestal extends beyond the footprint of the die by greater than 500 micrometers.

9. The microelectronic package of claim 8, wherein the footprint of the pedestal extends beyond the footprint of the die by between 500 micrometers and 1 millimeter.

10. The microelectronic package of claim 7, wherein the pedestal includes a cavity, and the cavity of the pedestal is coupled with the STIM.

11. The microelectronic package of claim 7, wherein the STIM includes indium.

12. The microelectronic package of claim 7, wherein the pedestal includes a face that is coupled with the STIM, and wherein the face is not parallel to a face of the die to which the STIM is coupled.

13. The microelectronic package of claim 7, wherein the pedestal is to control bleed-out of the STIM during STIM reflow.

14. A microelectronic package comprising:
a die;
a solder thermal interface material (STIM) coupled with the die; and
an integrated heat spreader (IHS) wherein the IHS includes a cavity in the IHS, and the STIM is coupled with the IHS inside the cavity.

15. The microelectronic package of claim 14, wherein the cavity has a footprint that is greater than a footprint of the die.

16. The microelectronic package of claim 15, wherein the footprint of the cavity is greater than the footprint of the die by at least 1 millimeter.

17. The microelectronic package of claim 14, wherein the cavity extends beyond the die by at least 500 nanometers around a periphery of the die.

18. The microelectronic package of claim 14, wherein the cavity is to control bleed-out of the STIM during a STIM reflow process.

19. The microelectronic package of claim 14, wherein a face of the cavity to which the STIM is coupled has a non-linear profile.

20. The microelectronic package of claim 14, wherein the STIM includes indium.
